(19) United States
(12) Patent Application Publication
(10) Pub. No.: US 2026/0363091 A1
(43) Pub. Date: Nov. 12, 2026

(54) SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/318,385

(22) Filed: Sep. 4, 2025

(30) Foreign Application Priority Data
May 7, 2025 (KR) 10-2025-0058798

(51) Int. Cl. H10W 46/00; H10B 43/30; H10B 43/40; H10B 80/00; H10W 90/00; H10W 90/20

(52) U.S. Cl. CPC H10W 46/00; H10B 43/30; H10B 43/40; H10W 90/00; H10B 80/00; H10W 46/301; H10W 46/503; H10W 90/297; H10W 90/792

(57) ABSTRACT

According to embodiments of the present disclosure, a semiconductor device may include: a substrate including a chip region and a scribe lane region disposed around the chip region; a bonding pad disposed on the substrate; a plurality of dummy wirings connected to the bonding pad, located in the scribe lane region, arranged in a first direction, and including a first dummy wiring and a second dummy wiring disposed adjacent to each other in a second direction intersecting the first direction; and a first insulating layer disposed on side surfaces and bottom surfaces of the plurality of dummy wirings, including a first overlap region located between the first dummy wiring and the second dummy wiring in the second direction, wherein a first air gap is disposed in the first overlap region.

### CROSS-REFERENCE TO RELATED APPLICATIONS

The present application claims priority under 35 U.S.C. 119(a) to Korean patent application number 10-2025-0058798 filed on May 7, 2025, which is incorporated herein by reference in its entirety.

### BACKGROUND

### 1. Technical Field

Embodiments of the present disclosure relate to a semiconductor device.

### 2. Related Art

Chips of a semiconductor device are separated in a scribe lane region located around a chip region or a guard ring region. As the degree of integration of semiconductor devices increases, it becomes more difficult to separate chips, resulting in the occurrence of defective chips during separation. Therefore, there is a need for a chip separation technique that minimizes the occurrence of defective chips.

### SUMMARY

The objects of the embodiments of the present disclosure are not limited to those described herein, and other objects not explicitly stated will be clearly understood by those skilled in the art from the following description.

Embodiments of the present disclosure may provide a semiconductor device capable of minimizing the occurrence of defective chips during chip separation.

Embodiments of the present disclosure may provide a semiconductor device including a substrate including a chip region and a scribe lane region disposed around the chip region; a bonding pad disposed on the substrate; a plurality of dummy wirings connected to the bonding pad, arranged in a first direction within the scribe lane region, and including a first dummy wiring and a second dummy wiring disposed adjacent to each other in a second direction intersecting the first direction; and a first insulating layer disposed on side surfaces and bottom surfaces of the plurality of dummy wirings, including a first overlap region located between the first dummy wiring and the second dummy wiring in the second direction, wherein a first air gap is disposed in the first overlap region.

Embodiments of the present disclosure may provide a semiconductor device including a first semiconductor structure and a second semiconductor structure each including a chip region and a scribe lane region located around the chip region, where the first semiconductor structure includes a peripheral circuit and a peripheral bonding pad connected to the peripheral circuit, and where the second semiconductor structure includes a cell bonding pad bonded to the peripheral bonding pad; a plurality of dummy wirings disposed in the scribe lane region and connected to the cell bonding pad; and a first insulating layer covering side surfaces and bottom surfaces of the plurality of dummy wirings, wherein a first air gap is disposed between the plurality of dummy wirings.

Embodiments of the present disclosure may provide a semiconductor device including a substrate including a chip region and a scribe lane region located around the chip region; a plurality of dummy wirings disposed in the scribe lane region on the substrate, arranged in a first direction, and including a first dummy wiring and a second dummy wiring adjacent to each other in a second direction intersecting the first direction; and a first insulating layer disposed on side surfaces and bottom surfaces of the plurality of dummy wirings, including a first overlap region located between the first dummy wiring and the second dummy wiring in the second direction, where a width of the first overlap region in the first direction is less than a width of the first dummy wiring in the first direction, and where an air gap is disposed in the first overlap region.

According to embodiments of the present disclosure, a semiconductor device may be provided that minimizes the occurrence of defective chips during chip separation.

The effects of the embodiments of the present disclosure are not limited to those described above, and additional effects not explicitly mentioned will be clearly understood by those skilled in the art from the description of the claims.

### BRIEF DESCRIPTION OF THE DRAWINGS

The present disclosure will be more clearly understood from the following detailed description and the accompanying drawings. The detailed description and drawings are provided solely for the purpose of explanation and do not limit the scope of the present disclosure.

FIG. 1 illustrates an example of a planar structure of a semiconductor device according to embodiments of the present disclosure.

FIG. 2 illustrates an example of a cross-sectional structure taken along line A-A′ of FIG. 1.

FIG. 3 is an enlarged view of element 298 in FIG. 2.

FIG. 4 is an enlarged view of element 299 in FIG. 2.

FIG. 5 to FIG. 9 illustrate other examples of planar structures of semiconductor devices according to embodiments of the present disclosure.

FIG. 10 to FIG. 19 illustrate portions of a method of manufacturing a semiconductor device according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

In the accompanying drawings, two directions parallel to an upper surface of a substrate are defined as a first direction FD and a second direction SD, respectively, and a direction protruding perpendicularly from the upper surface of the substrate is defined as a third direction VD. The first direction FD and the second direction SD may be substantially perpendicular to each other. The third direction VD is a direction perpendicular to both the first direction FD and the second direction SD. Hereinafter, in the present specification, “perpendicular” or “perpendicular direction” will be used to refer to the third direction VD. A direction indicated by an arrow in a drawing and its opposite direction represent the same direction.

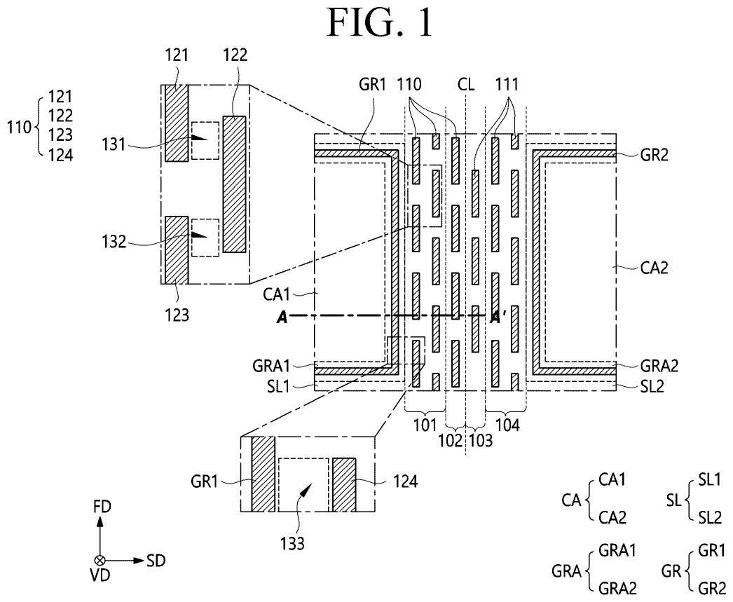

FIG. 1 illustrates an example of a planar structure of a semiconductor device according to embodiments of the present disclosure. FIG. 1 may illustrate a state in which semiconductor devices are formed on a single wafer prior to being separated into individual chips.

Referring to FIG. 1, a chip region CA may include a first chip region CA1 and a second chip region CA2. The first chip region CA1 and the second chip region CA2 may be spaced apart from each other. The first chip region CA1 and the second chip region CA2 may each refer to a region in which elements and wirings constituting a single semiconductor device are disposed. For example, elements and wirings disposed in the first chip region CA1 may belong to a different semiconductor device from those disposed in the second chip region CA2.

A guard ring region GRA may include a first guard ring region GRA1 and a second guard ring region GRA2. The first guard ring region GRA1 may be disposed around the first chip region CA1 and may surround the first chip region CA1. Similarly, the second guard ring region GRA2 may be disposed around the second chip region CA2 and may surround the second chip region CA2. A guard ring GR may include a first guard ring GR1 and a second guard ring GR2. The first guard ring region GRA1 and the second guard ring region GRA2 may each refer to a region in which the guard ring GR is disposed.

A scribe lane region SL may include a first scribe lane region SL1 and a second scribe lane region SL2. The first scribe lane region SL1 may be disposed around the first guard ring region GRA1 and may surround the first guard ring region GRA1. The second scribe lane region SL2 may be disposed around the second guard ring region GRA2 and may surround the second guard ring region GRA2. The second scribe lane region SL2 may be continuous with the first scribe lane region SL1. The first scribe lane region SL1 may include a first inner region 101 and a first outer region 102. The second scribe lane region SL2 may include a second outer region 103 and a second inner region 104.

The first scribe lane region SL1 and the second scribe lane region SL2 may be separated by a cutting line CL. In one embodiment, the first scribe lane region SL1 and the second scribe lane region SL2 may be separated from each other by a cutting process. The first scribe lane region SL1 and the second scribe lane region SL2 may belong to different semiconductor devices.

In one embodiment, the first chip region CA1, the first guard ring region GRA1, and the first scribe lane region SL1 may be included in a single semiconductor device (e.g., a first semiconductor device). The second chip region CA2, the second guard ring region GRA2, and the second scribe lane region SL2 may be included in another semiconductor device different from the first semiconductor device (e.g., a second semiconductor device).

Hereinafter, for convenience, the semiconductor device according to embodiments of the present disclosure will be referred to as the first semiconductor device.

The guard ring GR may include the first guard ring GR1 and the second guard ring GR2. The first guard ring GR1 may be disposed in the first guard ring region GRA1. The second guard ring GR2 may be disposed in the second guard ring region GRA2. The first guard ring GR1 may surround the first chip region CA1, and the second guard ring GR2 may surround the second chip region CA2.

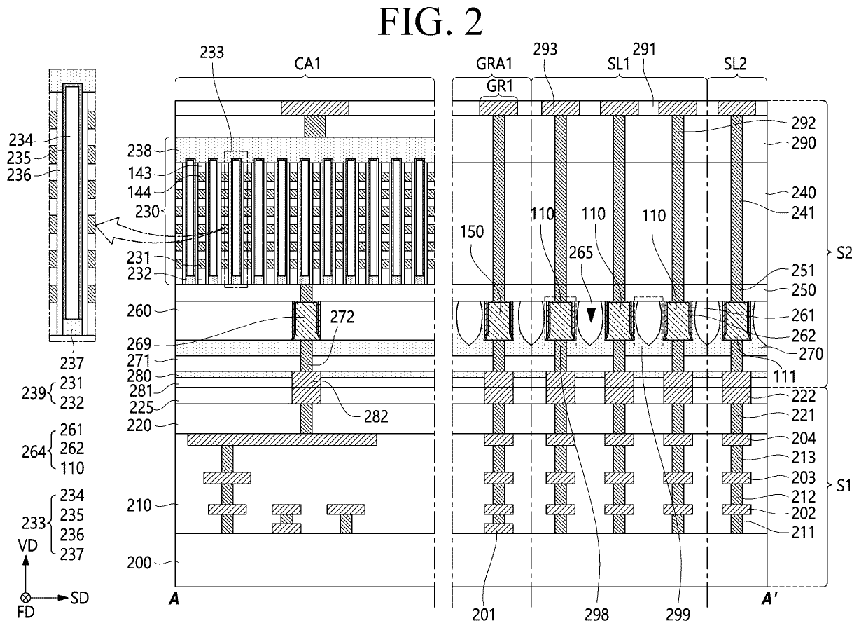

FIG. 2 illustrates an example of a cross-sectional structure taken along line A-A′ of FIG. 1.

Referring to FIG. 1 and FIG. 2, a plurality of dummy wirings 110 may be disposed in the first scribe lane region SL1. The structure in which the plurality of dummy wirings 110 are disposed is not limited thereto. In one embodiment, the plurality of dummy wirings 110 may have the same width in the first direction FD or the second direction SD. In one embodiment, the plurality of dummy wirings 110 may be spaced apart from each other in the first direction FD and the second direction SD. In one embodiment, when viewed in the first direction FD, adjacent dummy wirings 110 may be entirely blocked by one another. In one embodiment, when viewed in the second direction SD, adjacent dummy wirings 110 may be entirely or partially blocked by one another. In one embodiment, the plurality of dummy wirings 110 may be disposed in a zigzag pattern in the first direction FD or the second direction SD.

An air gap 265 may be disposed between the plurality of dummy wirings 110, in an overlap region that is entirely located between adjacent ones of the plurality of dummy wirings 110 in the second direction SD.

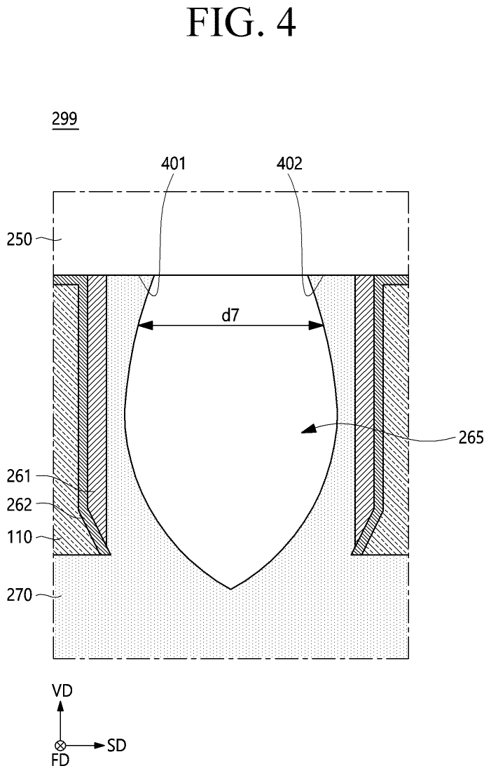

In addition, the air gap 265 may be disposed in an overlap region that is entirely located between and the first guard ring GR1 and a dummy wiring, among the plurality of dummy wirings 110, adjacent to the first chip region CA1. The structure of the air gap 265 is described in detail with reference to FIG. 2 and FIG. 4.

In one embodiment, as shown in FIG. 1, the plurality of dummy wirings 110 may include a first dummy wiring 121, a second dummy wiring 122, and a third dummy wiring 123. Further, the plurality of dummy wirings 110 may include a fourth dummy wiring 124.

The first dummy wiring 121 and the third dummy wiring 123 may be spaced apart from each other in the first direction FD. When viewed in the first direction FD, the first dummy wiring 121 and the third dummy wiring 123 may be entirely blocked by each other. The second dummy wiring 122 may not be blocked by either the first dummy wiring 121 or the third dummy wiring 123 when viewed in the first direction FD.

In the first scribe lane region SL1, a first overlap region 131 may be disposed entirely between a first dummy wiring 121 and a second dummy wiring 122 in the second direction SD. In the first scribe lane region SL1, a second overlap region 132 may be disposed entirely between the second dummy wiring 122 and a third dummy wiring 123 in the second direction SD. The first overlap region 131 and the second overlap region 132 may be spaced apart from each other in the first direction FD. The air gap 265 (or, for example, air gaps 265) may be disposed in the first overlap region 131 and the second overlap region 132. The first overlap region 131 and the second overlap region 132 may be located within a first insulating layer 270. A width of the overlap regions mentioned below, including the first overlap region 131, in the first direction FD may be less than or equal to a width of an adjacent dummy wiring or a guard ring in the first direction FD. A plurality of dummy wirings other than the first dummy wiring 121, the second dummy wiring 122, and the third dummy wiring 123 may be repeatedly disposed in the first direction FD and the second direction SD with reference to the structure of the first dummy wiring 121, the second dummy wiring 122, and the third dummy wiring 123 described above.

The first guard ring GR1 may be adjacent to at least one of the plurality of dummy wirings 110 (e.g., the fourth dummy wiring 124). As a result, a third overlap region 133 may be disposed in the first guard ring region GRA1 or the first scribe lane region SL1, and may be entirely located between the first guard ring GR1 and the fourth dummy wiring 124 in the second direction SD. The air gap 265 (for example, an additional air gap 265) may be disposed in the third overlap region 133. third overlap region 133 may be located within the first insulating layer 270.

The air gap 265 may be disposed in an overlap region that is entirely located, in the second direction SD, between: a dummy wiring among adjacent dummy wirings 111 disposed in the second scribe lane region SL2 and positioned farthest from the second chip region CA2, and a dummy wiring among the plurality of dummy wirings 110 disposed in the first scribe lane region SL1 and positioned farthest from the first chip region CA1.

Referring to FIG. 2, the first semiconductor device may include the first chip region CA1, the first guard ring region GRA1, and the first scribe lane region SL1. The second scribe lane region SL2 may be disposed at a side of the first scribe lane region SL1 in the second direction SD.

The first semiconductor device may include a first semiconductor structure S1 and a second semiconductor structure S2. The first semiconductor structure S1 and the second semiconductor structure S2 may be bonded together. Specifically, a bottom surface of the second semiconductor structure S2 may be bonded to a top surface of the first semiconductor structure S1. An interface between the first semiconductor structure S1 and the second semiconductor structure S2 may be referred to as a bonding interface.

The first semiconductor structure S1 of the first semiconductor device may include a second substrate 200, a gate 201, lower wirings 202, 203, and 204, lower contacts 211, 212, and 213, a first bonding contact 221, a first bonding pad 222, a first bonding insulating layer 225, a first lower insulating layer 210, and a second lower insulating layer 220.

The second substrate 200 may include a semiconductor substrate such as a silicon wafer or a silicon-on-insulator (SOI) wafer. The second substrate 200 may include a group III-V compound semiconductor substrate such as gallium arsenide (GaAs). The second substrate 200 may include monocrystalline silicon, polysilicon, amorphous silicon, monocrystalline silicon-germanium, polycrystalline silicon-germanium, carbon-doped silicon, or a combination thereof.

On the second substrate 200, the gate 201, the lower contacts 211, 212, and 213, the lower wirings 202, 203, and 204, and the first lower insulating layer 210 may be disposed. The lower contacts 211, 212, and 213 may be disposed between the lower wirings 202, 203, and 204, or between the first lower wiring 202 and the second substrate 200. The lower contacts 211, 212, and 213 may be electrically connected to the lower wirings 202, 203, and 204. The gate 201, the first lower contact 211, and the first lower wiring 202 may constitute a transistor.

On the first lower insulating layer 210 and the third lower wiring 204, the second lower insulating layer 220 may be disposed. The first bonding contact 221 may be disposed in the second lower insulating layer 220 and may be connected to a corresponding third lower wiring 204.

On the second lower insulating layer 220 and the first bonding contact 221, the first bonding insulating layer 225 may be disposed. The first bonding pad 222 may be disposed in the first bonding insulating layer 225 and may be connected to a corresponding first bonding contact 221. An upper surface of the first bonding pad 222 may be substantially coplanar with an upper surface of the first bonding insulating layer 225.

The gate 201, the lower contacts 211, 212, and 213, the lower wirings 202, 203, and 204, the first bonding contact 221, and the first bonding pad 222 may include a conductive material such as metal, metal oxide, metal nitride, metal silicide, polysilicon, conductive carbon, or a combination thereof. The first lower insulating layer 210, the second lower insulating layer 220, and the first bonding insulating layer 225 may include silicon oxide, silicon nitride, silicon oxynitride, a high-k dielectric material, or a combination thereof.

On the first semiconductor structure S1, the second semiconductor structure S2 may be disposed. The second semiconductor structure S2 may include a first wiring 269, upper wirings 293, dummy wirings 110, a guard ring wiring 150, a spacer 261, a barrier layer 262, upper contacts 251, 241, and 292, a first insulating layer 270, a second insulating layer 260, a second upper insulating layer 250, a first upper insulating layer 271, a third upper insulating layer 240, a fourth upper insulating layer 290, a fifth upper insulating layer 291, a memory cell array 230, a second bonding insulating layer 281, a third bonding insulating layer 280, a second bonding contact 272, and a second bonding pad 282.

In the first chip region CA1, the first guard ring region GRA1, and the first scribe lane region SL1, the second bonding insulating layer 281 may be disposed on the first bonding insulating layer 225 of the first semiconductor structure. The third bonding insulating layer 280 may be disposed on the second bonding insulating layer 281. The second bonding pad 282 may be disposed on the first bonding pad 222 of the first semiconductor structure S1 and may be embedded in the second bonding insulating layer 281 and the third bonding insulating layer 280. A bottom surface of the second bonding pad 282 may be substantially coplanar with a bottom surface of the second bonding insulating layer 281. The bottom surface of the second bonding pad 282 may contact an upper surface of the corresponding first bonding pad 222. In one embodiment, the second bonding pad 282 may be bonded to the first bonding pad 222. The upper surface of the first bonding insulating layer 225 may contact the bottom surface of the second bonding insulating layer 281. In one embodiment, the second bonding insulating layer 281 may be bonded to the first bonding insulating layer 225.

In the first chip region CA1, the first guard ring region GRA1, and the first scribe lane region SL1, the second upper insulating layer 250 may be disposed on the third bonding insulating layer 280 and the second bonding pad 282. The first insulating layer 270 may be disposed on the second upper insulating layer 250. A second bonding contact 272 may be disposed in the first insulating layer 270 and the second upper insulating layer 250. The second bonding contact 272 may be located on an upper surface of the second bonding pad 282 and may be connected to a corresponding one of the second bonding pads 282.

The second bonding pad 282 and the second bonding contact 272 may include a conductive material such as metal, metal oxide, metal nitride, metal silicide, polysilicon, conductive carbon, or a combination thereof. The second bonding insulating layer 281, the third bonding insulating layer 280, the first upper insulating layer 271, and the first insulating layer 270 may include silicon oxide, silicon nitride, silicon oxynitride, a high-k dielectric material, or a combination thereof.

In the first chip region CA1, the second insulating layer 260 may be disposed on the first insulating layer 270. The first wiring 269 may be disposed in the second insulating layer 260, and the second insulating layer 260 may surround side surfaces of the first wiring 269. A bottom surface of the first wiring 269 may be in contact with an upper surface of a corresponding second bonding contact 272. An upper surface of the first wiring 269 may be substantially coplanar with an upper surface of the second insulating layer 260.

In the first chip region CA1, the second upper insulating layer 250 may be disposed on the second insulating layer 260. A first upper contact 251 may be located in the second upper insulating layer 250. The first upper contact 251 may be disposed on the first wiring 269 and connected thereto. The memory cell array 230 may be disposed on the first upper contact 251 and the second insulating layer 260.

The memory cell array 230 may include a stacked structure 239, a channel structure 233, and a source plate 238. The stacked structure 239 may have interlayer insulating layers 232 and electrode layers 231 alternately stacked in a vertical direction.

The channel structure 233 may vertically penetrate through the interlayer insulating layers 232 and the electrode layers 231. The channel structure 233 may extend into the source plate 238 in the vertical direction. An upper surface of the channel structure 233 may be located higher than a bottom surface of the source plate 238 in the vertical direction. A bottom surface of the channel structure 233 may be substantially coplanar with a bottom surface of the lowest interlayer insulating layer 232 in the memory cell array 230.

The channel structure 233 may be connected to a corresponding first upper contact 251. The channel structure 233 may be connected to the first semiconductor structure S1 via a corresponding first upper contact 251, a first wiring 269 corresponding to the first upper contact 251, a second bonding pad 282 corresponding to the first wiring 269, a first bonding pad 222 connected to the second bonding pad 282, and a first bonding contact 221 corresponding to the first bonding pad 222.

The channel structure 233 may include a core layer 234, a channel pattern 235, a data storage pattern 236, and a drain pad 237. In one embodiment, the data storage pattern 236 may include a tunnel insulating layer (not shown), a charge trap layer (not shown), and a blocking layer (not shown).

The drain pad 237 may contact an upper surface of the first upper contact 251. The core layer 234 may be disposed on the drain pad 237 and may extend in the vertical direction. The channel pattern 235 may surround side and bottom surfaces of the core layer 234 and may extend into the source plate 238 in the vertical direction. The data storage pattern 236 may surround side surfaces of the channel pattern 235 and the drain pad 237. A single electrode layer 231, the data storage pattern 236, and a portion of the channel pattern 235 overlapping the electrode layer 231 in the first direction FD or the second direction SD may constitute a single memory cell.

A source plate 238 may be disposed on the interlayer insulating layer 232 located at the top of the memory cell array 230 and on the channel structure 233.

A fourth upper insulating layer 290 and a third upper contact 292 may be disposed on the source plate 238. The third upper contact 292 may penetrate the fourth upper insulating layer 290 in the vertical direction and may be connected to the source plate 238. A fifth upper insulating layer 291 and an upper wiring 293 may be disposed on the fourth upper insulating layer 290 and the third upper contact 292. The upper wiring 293 may penetrate the fifth upper insulating layer 291 in the vertical direction and may be connected to the third upper contact 292.

The first upper contact 251, the third upper contact 292, the electrode layer 231, the drain pad 237, the first wiring 269, and the upper wiring 293 may include a conductive material such as metal, metal oxide, metal nitride, metal silicide, polysilicon, conductive carbon, or a combination thereof. The channel pattern 235 and the source plate 238 may include a semiconductor material such as polysilicon. The second insulating layer 260, the fourth upper insulating layer 290, and the fifth upper insulating layer 291 may include silicon oxide, silicon nitride, silicon oxynitride, a high-k dielectric material, or a combination thereof.

In the first guard ring region GRA1 and the first scribe lane region SL1, the guard ring wiring 150 and the plurality of dummy wirings 110 may be located within the first insulating layer 270. In one embodiment, the first insulating layer 270 may be located on side surfaces and bottom surfaces of the plurality of dummy wirings 110. The guard ring wiring 150 and the plurality of dummy wirings 110 may be disposed on the second bonding contact 272. Bottom surfaces of the guard ring wiring 150 and the dummy wirings 110 may contact an upper surface of the second bonding contact 272. Upper surfaces of the guard ring wiring 150 and the dummy wirings 110 may be substantially coplanar with an upper surface of the first insulating layer 270.

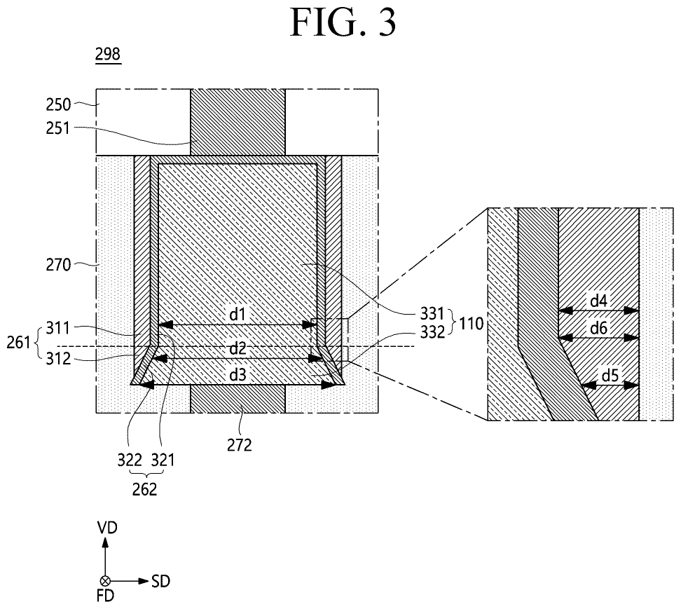

A barrier layer 262 may be disposed on upper surfaces and side surfaces of each of the plurality of dummy wirings 110. A spacer 261 may be disposed on side surfaces of the plurality of dummy wirings 110. A wiring structure 264 may be defined to include one or more of the plurality of dummy wirings 110, the barrier layer 262, and the spacer 261. For example, the wiring structure 264 may include the first dummy wiring 121, the barrier layer 262 surrounding upper and side surfaces of the first dummy wiring 121, and the spacer 261 disposed on side surfaces of the barrier layer 262. In the case of the guard ring wiring 150, the barrier layer 262 may also be disposed on its upper and side surfaces. In addition, the spacer 261 may be disposed on a side surface of the guard ring wiring 150. The specific structure of the wiring structure 264 is described in detail with reference to FIG. 3.

The air gap 265 may be disposed on side surfaces of the guard ring wiring 150 and the plurality of dummy wirings 110. The air gap 265 may be located within the first insulating layer 270. The air gap 265 may also be disposed on side surfaces of adjacent dummy wirings 111 disposed in the second scribe lane adjacent to the first scribe lane region SL1. In one embodiment, the air gap 265 may be disposed between the first guard ring GR1 and the first wiring 269 in the second direction SD. In one embodiment, the air gap 265 may be disposed in an overlap region that is entirely located between one of the plurality of dummy wirings 110 and the first guard ring GR1 in the second direction SD. In one embodiment, the air gap 265 may be disposed in an overlap region that is entirely located between two adjacent dummy wirings among the plurality of dummy wirings 110 in the second direction SD. In one embodiment, the air gap 265 may be disposed in an overlap region that is entirely located, in the second direction SD, between a dummy wiring among the adjacent dummy wirings 111, which is positioned closest to the first chip region CA1, and a dummy wiring among the plurality of dummy wirings 110, which is positioned farthest from the first chip region CA1.

The air gap 265 may be disposed between a dummy wiring among the dummy wirings 110 that is farthest from the first chip region CA1 and any one of the adjacent dummy wirings 111. In one embodiment, the air gap 265 may be disposed between dummy wirings 110 and adjacent dummy wirings 111 that are farthest from the first chip region CA1 and the second chip region CA2, respectively. When the first chip region CA1 and the second chip region CA2 are separated into individual semiconductor devices based on the cutting line CL, the separation path may pass through the air gap 265 located between the dummy wiring farthest from the first chip region CA1 in the first scribe lane region SL1 and the dummy wiring farthest from the second chip region CA2 in the second scribe lane region SL2. As a result, a trace of the air gap 265 may remain on a side surface of the dummy wiring farthest from the first chip region CA1 among the dummy wirings 110. In other words, when the semiconductor chip is viewed from outside, a recessed structure directed toward the chip region CA may be formed on the outer side surface of the chip corresponding to the first insulating layer 270. The detailed structure of the air gap 265 is described in detail with reference to FIG. 4.

In the first guard ring region GRA1 and the first scribe lane region SL1, a second upper insulating layer 250 may be disposed on the first insulating layer 270. A first upper contact 251 may be located in the second upper insulating layer 250. The first upper contact 251 may be disposed on the guard ring wiring 150 and the plurality of dummy wirings 110. A bottom surface of the first upper contact 251 may contact an upper surface of the guard ring wiring 150 and an upper surface of the dummy wirings 110. The first upper contact 251 may be connected to the guard ring wiring 150 and each of the dummy wirings 110.

On the second upper insulating layer 250, a third upper insulating layer 240, a fourth upper insulating layer 290, and a fifth upper insulating layer 291 may be sequentially stacked. A second upper contact 241 and the third upper contact 292 may be located in the third upper insulating layer 240 and the fourth upper insulating layer 290, respectively. The upper wiring 293 may be located in the fifth upper insulating layer 291. The second upper contact 241 and the third upper contact 292 may be sequentially disposed on the first upper contact 251. The upper wiring 293 may be disposed on the third upper contact 292. The first upper contact 251 may be connected to the upper wiring 293 via the second upper contact 241 and the third upper contact 292.

The guard ring wiring 150, the plurality of dummy wirings 110, the barrier layer 262, the first upper contact 251, the second upper contact 241, the third upper contact 292, and the upper wiring 293 may include a conductive material such as metal, metal oxide, metal nitride, metal silicide, polysilicon, conductive carbon, or a combination thereof. The spacer 261, the second upper insulating layer 250, the third upper insulating layer 240, the fourth upper insulating layer 290, and the fifth upper insulating layer 291 may include silicon oxide, silicon nitride, silicon oxynitride, a high-k dielectric material, or a combination thereof.

FIG. 3 is an enlarged view of element 298 in FIG. 2.

Referring to FIG. 3, the wiring structure 264 may include one of the plurality of dummy wirings 110, the barrier layer 262, and the spacer 261. Hereinafter, one of the plurality of dummy wirings 110 will be referred to as the first dummy wiring 121. The barrier layer 262 may surround the side surfaces and upper surface of the first dummy wiring 121. The spacer 261 may be disposed on the side surface of the barrier layer 262. In one embodiment, the spacer 261 may be disposed on the side surface of the first dummy wiring 121.

Referring to FIG. 3, the first dummy wiring 121 may include a first wiring portion 331 and a second wiring portion 332. The first wiring portion 331 may be located on the second wiring portion 332. The second wiring portion 332 may be continuous with the first wiring portion 331. Side surfaces of the cross section of the first wiring portion 331 may be parallel to each other. A width d1 of the first wiring portion 331 in the second direction SD may be constant. Side surfaces of the cross section of the second wiring portion 332 may not be parallel and may curve outward toward the bottom. A width d2 of the second wiring portion 332 in the second direction SD may increase toward the bottom. A maximum width d3 of the second wiring portion 332 in the second direction SD may be greater than the width d1 of the first wiring portion 331 in the second direction SD.

The barrier layer 262 may include a first barrier portion 321 and a second barrier portion 322. The first barrier portion 321 may be disposed on the side surfaces and upper surface of the first wiring portion 331. The second barrier portion 322 may be disposed on the side surfaces and upper surface of the second wiring portion 332. The second barrier portion 322 may protrude further in the second direction SD toward the bottom.

The spacer 261 may be disposed on a side surface of the first dummy wiring 121 or on a side surface of the barrier layer 262. The spacer 261 may include a first spacer portion 311 and a second spacer portion 312. The first spacer portion 311 may be disposed on the side surface of the first barrier portion 321. The second spacer portion 312 may be disposed on the side surface of the second barrier portion 322. A cross section of the first spacer portion 311 may have side surfaces that are parallel in the vertical direction. A width d4 of the first spacer portion 311 in the second direction SD may be constant. The cross-section of the second spacer portion 312 may be non-parallel in the vertical direction and may be curved outward toward the bottom. A width d5 of the second spacer portion 312 in the second direction SD may decrease toward the bottom. A maximum width d6 of the second spacer portion 312 in the second direction SD may be less than the width d4 of the first spacer portion 311 in the second direction SD.

An inner surface of the first barrier portion 321 may contact the first wiring portion 331. An outer surface of the first barrier portion 321 may contact the first spacer portion 311, the first upper insulating layer 271, and the first upper contact 251. An inner surface of the second barrier portion 322 may contact the first wiring portion 331 and the first insulating layer 270. An outer surface of the second barrier portion 322 may contact the second spacer portion 312 and the first insulating layer 270.

FIG. 4 is an enlarged view of element 299 in FIG. 2.

Referring to FIG. 4, the air gap 265 may be located within the first insulating layer 270. The air gap 265 may be disposed between the plurality of wiring structures 264. An insulating material of the first insulating layer 270 may be located between the spacer 261 of the wiring structure 264 and the air gap 265. In one embodiment, an entire surface of the air gap 265 in the second direction SD may be in contact with the insulating material of the first insulating layer 270. In another embodiment, a portion of the surface of the air gap 265 in the second direction SD may be in contact with a side surface of the spacer 261.

A width d7 of the air gap 265 in the second direction SD may vary in the vertical direction. Specifically, the width d7 of the air gap 265 in the second direction SD may be maintained, increased, or decreased along the vertical direction. In one embodiment, the width d7 of the air gap 265 in the second direction SD may repeatedly maintain, increase, and decrease along the vertical direction.

A first surface 401 and a second surface 402 may be located between adjacent wiring structures 264. The first surface 401 and the second surface 402 may be located in the same plane as the upper surface of the first insulating layer 270. The first surface 401 and the second surface 402 may refer to two-dimensional areas in which the insulating material of the first insulating layer 270 contacts a bottom surface of the second upper insulating layer 250 between adjacent wiring structures 264. The first surface 401 may be located on a side surface of one of the adjacent wiring structures 264, and the second surface 402 may be located on a side surface of the other one of the adjacent wiring structures 264. The first surface 401 and the second surface 402 may be spaced apart from each other in the same plane as the upper surface of the first insulating layer 270.

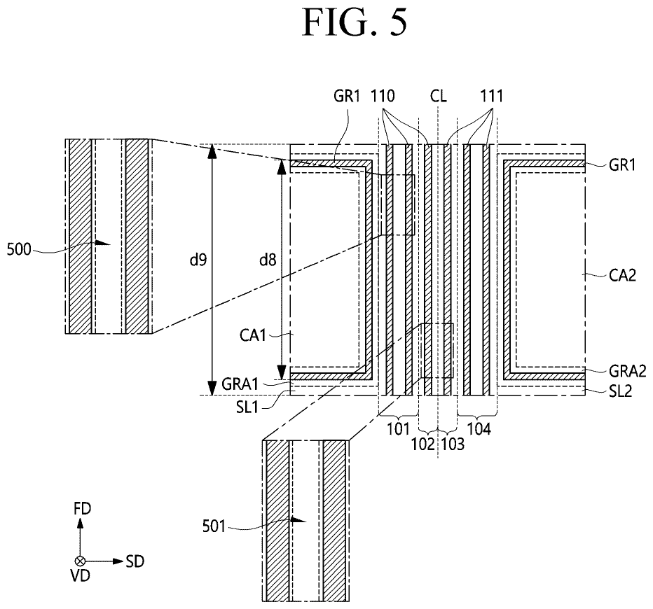

FIG. 5 through FIG. 9 are diagrams illustrating other examples of the planar structure of the semiconductor device according to embodiments of the present disclosure.

Referring to FIG. 5, the plurality of dummy wirings 110 in the first scribe lane region SL1 may be continuous in the first direction FD. A width d9 of the plurality of dummy wirings 110 in the first direction FD may be greater than a width d8 of the first guard ring GR1 in the first direction FD. Adjacent dummy wirings 111 disposed in the second scribe lane region SL2 adjacent to the first scribe lane region SL1 may also be continuous in the first direction FD. The plurality of dummy wirings 110 may be disposed in the first inner region 101 and the first outer region 102. The adjacent dummy wirings 111 may be disposed in the second outer region 103 and the second inner region 104. The air gap 265 may be disposed in an overlap region 500 entirely located between adjacent dummy wirings 110 in the second direction SD. In one embodiment, a width of the overlap region 500 between adjacent dummy wirings 110 in the first direction FD may be greater than a width of the first guard ring GR1 in the first direction FD.

Referring to FIG. 5, the air gap 265 may be disposed in an overlap region 501 that is entirely located, in the second direction SD, between a dummy wiring among the plurality of dummy wirings 110, which is positioned farthest from the first chip region CA1, and a dummy wiring among the adjacent dummy wirings 111, which is positioned farthest from the second chip region CA2.

In one embodiment, a width of the overlap region 501 in the first direction FD, which is entirely located in the second direction SD between a dummy wiring among the plurality of dummy wirings 110 positioned farthest from the first chip region CA1 and a dummy wiring among the adjacent dummy wirings 111 positioned farthest from the second chip region CA2, may be greater than a width of the first guard ring GR1 in the first direction FD.

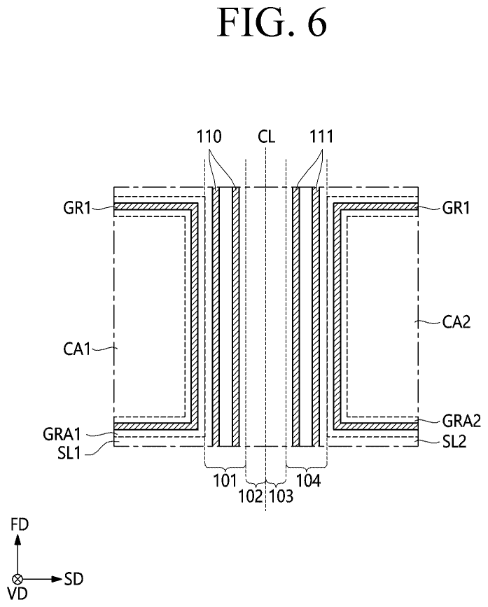

Referring to FIG. 6, in the first scribe lane region SL1, the plurality of dummy wirings 110 may not be disposed in the first outer region 102. In the second scribe lane region SL2, the adjacent dummy wirings 111 may not be disposed in the second outer region 103.

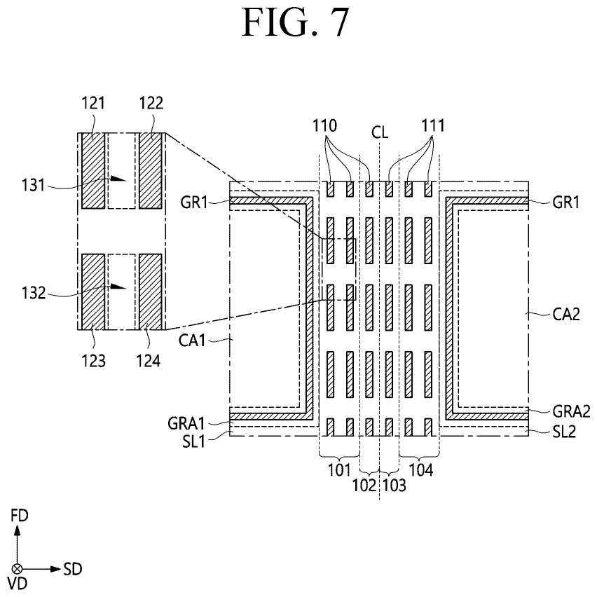

Referring to FIG. 7, the plurality of dummy wirings 110 in the first scribe lane region SL1 may be spaced apart from each other in the first direction FD and the second direction SD. In one embodiment, the spacing between the dummy wirings 110 in the first direction FD may be uniform. In another embodiment, the spacing between the dummy wirings 110 in the second direction SD may also be uniform.

Referring to FIG. 7, the dummy wirings 110 may include a first dummy wiring 121, a second dummy wiring 122, a third dummy wiring 123, and a fourth dummy wiring 124. The first dummy wiring 121 and the second dummy wiring 122 may be adjacent to each other in the second direction SD. The first dummy wiring 121 and the third dummy wiring 123 may be adjacent to each other in the first direction FD. The second dummy wiring 122 and the fourth dummy wiring 124 may be adjacent to each other in the first direction FD. The third dummy wiring 123 and the fourth dummy wiring 124 may be adjacent to each other in the second direction SD.

The first dummy wiring 121 and the second dummy wiring 122 may be completely obscured by each other when viewed in the second direction SD (for example, be coaxial, have identical profiles when superimposed from the direction SD). The third dummy wiring 123 and the fourth dummy wiring 124 may be completely obscured by each other when viewed in the second direction SD. The first dummy wiring 121 and the third dummy wiring 123 may be completely obscured by each other when viewed in the first direction FD. The second dummy wiring 122 and the fourth dummy wiring 124 may be completely obscured by each other when viewed in the first direction FD.

Referring to FIG. 7, a first overlap region 131 may be disposed in the first scribe lane region SL1. The first overlap region 131 may be entirely located, in the second direction SD, between the first dummy wiring 121 and the second dummy wiring 122. A second overlap region 132 may also be disposed in the first scribe lane region SL1, the second overlap region 132 being entirely located, in the second direction SD, between the third dummy wiring 123 and the fourth dummy wiring 124. The first overlap region 131 and the second overlap region 132 may be spaced apart from each other in the first direction FD. The air gap 265 may be disposed in the first overlap region 131 and the second overlap region 132. The first overlap region 131 and the second overlap region 132 may be located within the first insulating layer 270.

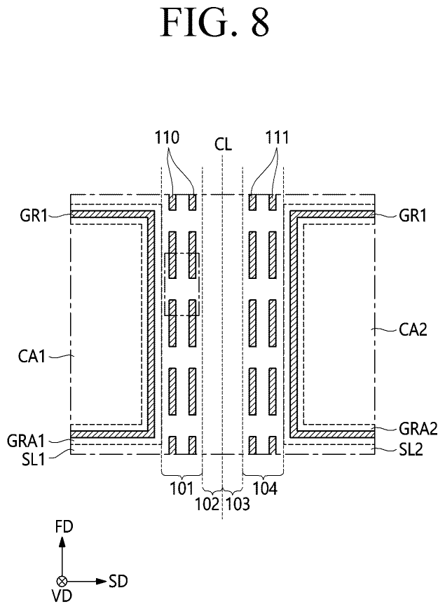

Referring to FIG. 8, the plurality of dummy wirings 110 described in FIG. 7 may not be disposed in the first outer region 102 of the first scribe lane region SL1.

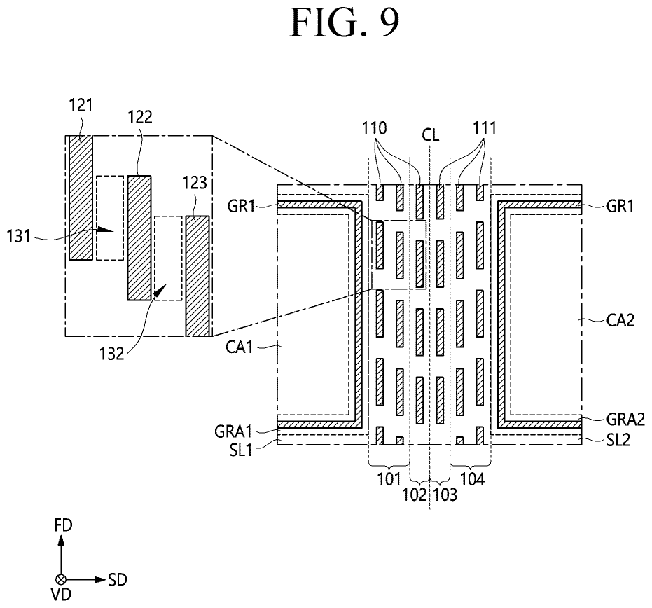

Referring to FIG. 9, the plurality of dummy wirings 110 in the first scribe lane region SL1 may be spaced apart from one another in both the first direction FD and the second direction SD. In one embodiment, the plurality of dummy wirings 110 may be arranged at uniform intervals in the first direction FD. In another embodiment, the plurality of dummy wirings 110 may be arranged at uniform intervals in the second direction SD.

Referring to FIG. 9, the plurality of dummy wirings 110 may include a first dummy wiring 121, a second dummy wiring 122, and a third dummy wiring 123. The first dummy wiring 121 and the second dummy wiring 122 may be adjacent to each other in the second direction SD. The second dummy wiring 122 and the third dummy wiring 123 may be adjacent to each other in the second direction SD.

The first dummy wiring 121 and the second dummy wiring 122 may be partially obscured by each other when viewed in the second direction SD. The second dummy wiring 122 and the third dummy wiring 123 may also be partially obscured by each other when viewed in the second direction SD. A first overlap region 131 may be disposed in the first scribe lane region SL1. The first overlap region 131 may be entirely located, in the second direction SD, between the first dummy wiring 121 and the second dummy wiring 122. A second overlap region 132 may also be disposed in the first scribe lane region SL1. The second overlap region 132 may be entirely located, in the second direction SD, between the second dummy wiring 122 and the third dummy wiring 123. Opposing ends of the first overlap region 131 in the first direction FD may be spaced apart, in the first direction FD, from corresponding opposing ends of the second overlap region 132. In other words, one side of the first overlap region 131 in the first direction FD may be spaced apart, in the first direction FD, from the corresponding side of the second overlap region 132. Additionally, the other side of the first overlap region 131 in the first direction FD may be spaced apart, in the first direction FD, from the corresponding other side of the second overlap region 132. In one embodiment, the first dummy wiring 121, the second dummy wiring 122, and third dummy wiring 123 may be arranged to be spaced apart from each other in the second direction SD, while being sequentially shifted forward in the first direction FD. The air gap 265 may be disposed in each of the first overlap region 131 and the second overlap region 132. The first overlap region 131 and the second overlap region 132 may be located within the first insulating layer 270. In one embodiment, the adjacent dummy wirings 111 in the second scribe lane region SL2 may be arranged symmetrically with respect to the cutting line CL, relative to the plurality of dummy wirings 110 disposed in the first scribe lane region SL1.

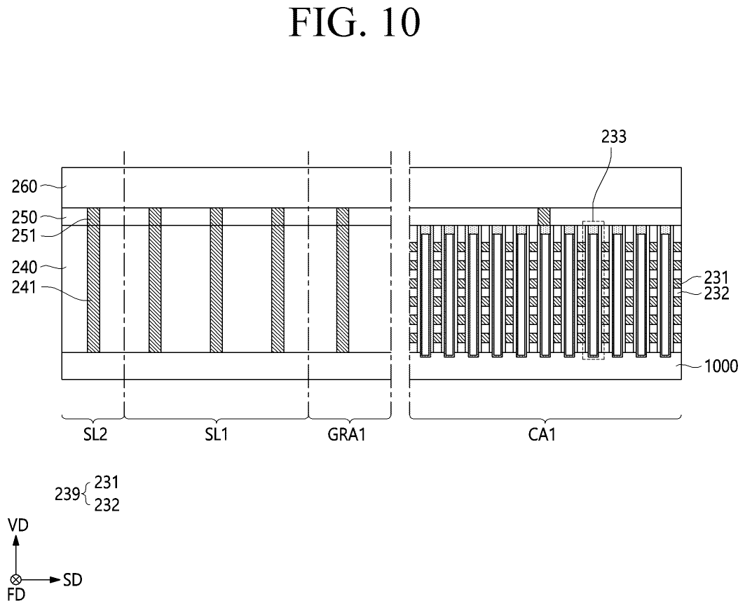

FIG. 10 through FIG. 19 are diagrams illustrating portions of a method for manufacturing a semiconductor device according to embodiments of the present disclosure.

Referring to FIG. 10, a first substrate 1000 is prepared. The first substrate 1000 may include a semiconductor substrate such as a silicon wafer or a silicon-on-insulator (SOI) wafer. The first substrate 1000 may include a group III-V compound semiconductor substrate, for example GaAs. The first substrate 1000 may include monocrystalline silicon, polysilicon, amorphous silicon, monocrystalline silicon germanium, polycrystalline silicon germanium, carbon-doped silicon, or a combination thereof.

Referring to FIG. 10, in the first chip region CA1, interlayer insulating layers 232 and electrode layers 231 may be alternately stacked on the first substrate 1000 to form a stacked structure 239. A channel structure 233 penetrating the interlayer insulating layers 232 and the electrode layers 231 in the vertical direction may be formed. In the first guard ring region GRA1 and the first scribe lane region SL1, a third upper insulating layer 240 may be formed on the first substrate 1000. After forming the third upper insulating layer 240, a second upper contact 241 penetrating the third upper insulating layer 240 may be formed. The process for forming the second upper contact 241 may include forming an etching structure in the third upper insulating layer 240, depositing a conductive material, and planarizing it. The planarization process may include grinding or chemical mechanical polishing (CMP). An upper surface of the third upper insulating layer 240 may be substantially coplanar with an upper surface of the second upper contact 241.

Referring to FIG. 10, a second upper insulating layer 250 may be formed over the third upper insulating layer 240, the channel structure 233, and the interlayer insulating layer 232. In the first chip region CA1, a first upper contact 251 may be formed to penetrate the second upper insulating layer 250. The first upper contact 251 may be connected to the corresponding channel structure 233. In the first guard ring region GRA1 and the first scribe lane region SL1, the first upper contact 251 may also be formed to penetrate the second upper insulating layer 250. The process of forming the first upper contact 251 may include forming an etching structure in the second upper insulating layer 250, depositing a conductive material, and planarizing it. The planarization process may include grinding or chemical mechanical polishing (CMP). The upper surface of the second upper insulating layer 250 may be substantially coplanar with the upper surface of the first upper contact 251. After the planarization process, a second insulating layer 260 may be formed on the second upper insulating layer 250 and the first upper contact 251.

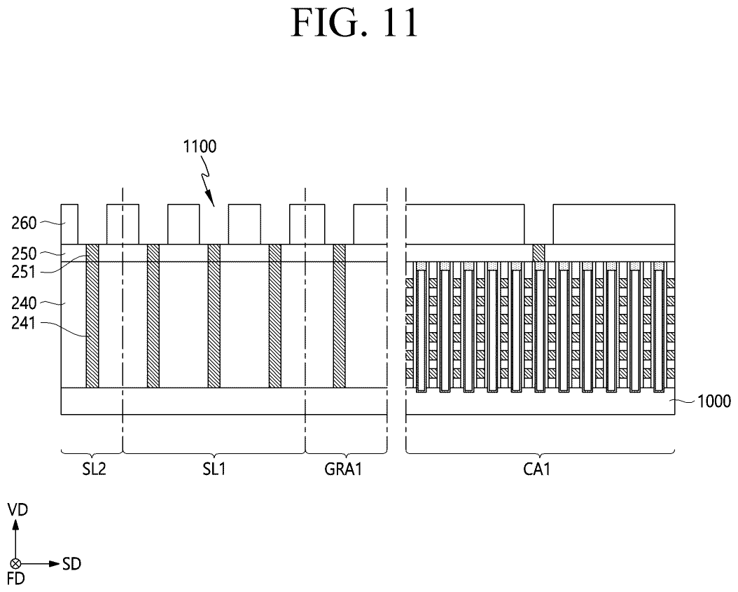

Referring to FIG. 11, a plurality of first trenches 1100 may be formed in the second insulating layer 260 at regions in contact with the upper surface of the first upper contact 251. As a result of forming the plurality of first trenches 1100, the upper surface of the first upper contact 251 may be exposed.

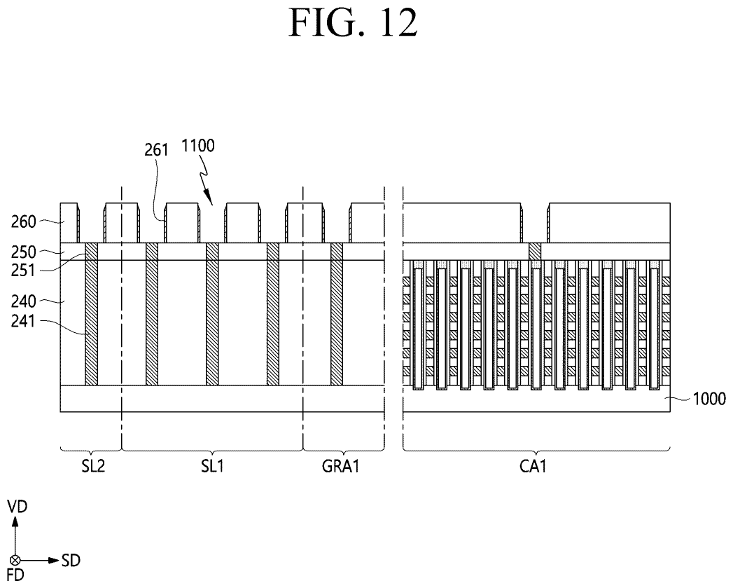

Referring to FIG. 12, spacers 261 may be respectively formed on sidewalls of the plurality of first trenches 1100 formed in FIG. 11. A process of forming the spacers 261 may include an etching process. For example, the spacer-forming process may include: depositing an insulating material on the second insulating layer 260, removing the insulating material located in the third direction VD within the second insulating layer 260 including the first trenches 1100, and leaving the insulating material on the sidewalls of the first trenches 1100. As a result of the etching process, the width of the spacer 261 in the second direction SD may decrease as it extends downward in the third direction VD. The insulating material may include silicon oxide, silicon nitride, silicon oxynitride, a low-k dielectric material, a high-k dielectric material, or a combination thereof.

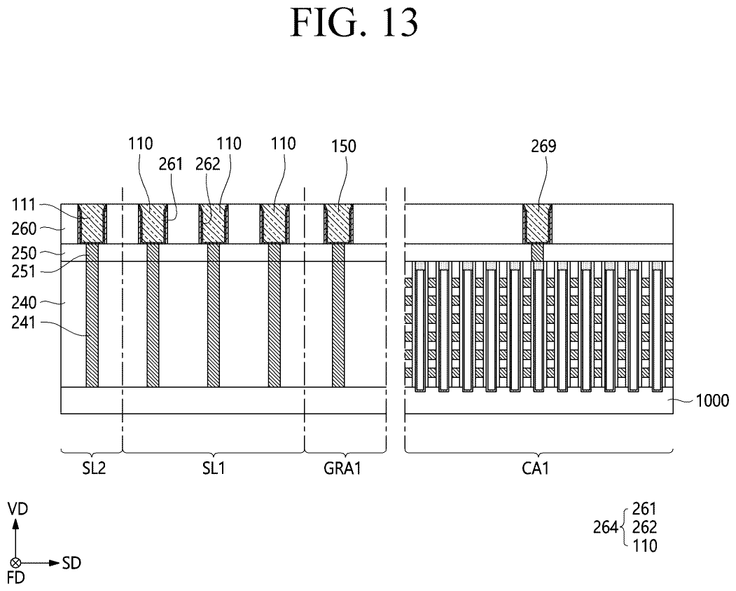

Referring to FIG. 13, a barrier layer 262 may be formed in the first trench 1100. An upper portion of the barrier layer 262 may protrude in the second direction SD. A guard ring wiring 150 may be formed in the first trench 1100 corresponding to the first guard ring region GRA1.

A plurality of dummy wirings 110 may be formed in the first trench 1100 corresponding to the first scribe lane region SL1. A first wiring 269 may be formed in the first trench 1100 corresponding to the first chip region CA1. The width of the guard ring wiring 150, the plurality of dummy wirings 110, and the first wiring 269 in the second direction SD may increase toward the bottom in the third direction VD. The spacers 261 may be disposed on side surfaces of the barrier layer 262, the guard ring wiring 150, the plurality of dummy wirings 110, and the first wiring 269. A process of forming the barrier layer 262, the guard ring wiring 150, the plurality of dummy wirings 110, and the first wiring 269 may include depositing and planarizing a conductive material. The planarization process may include a grinding process or a chemical mechanical polishing (CMP) process. The conductive material may include a metal, a metal oxide, a metal nitride, a metal silicide, polysilicon, conductive carbon, or a combination thereof.

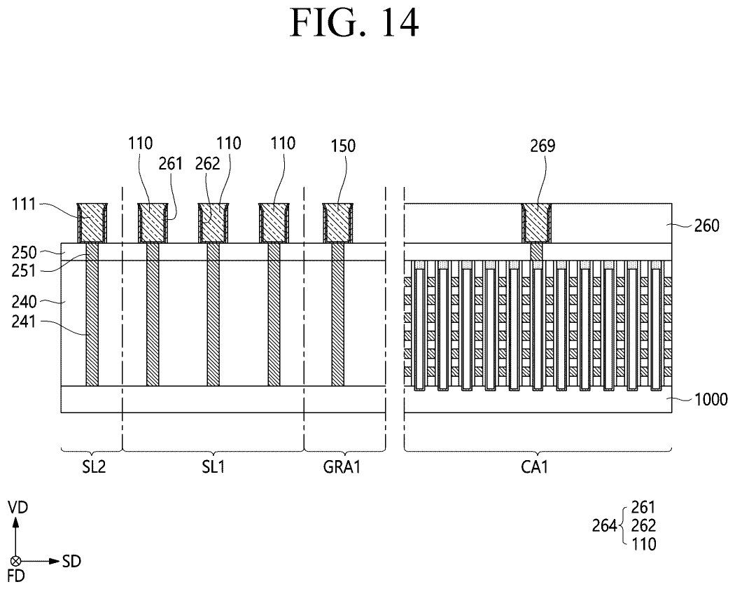

Referring to FIG. 14, the second insulating layer 260 in the first guard ring region GRA1 and the first scribe lane region SL1 may be removed. The process of removing the second insulating layer 260 may include a photolithography or etching process.

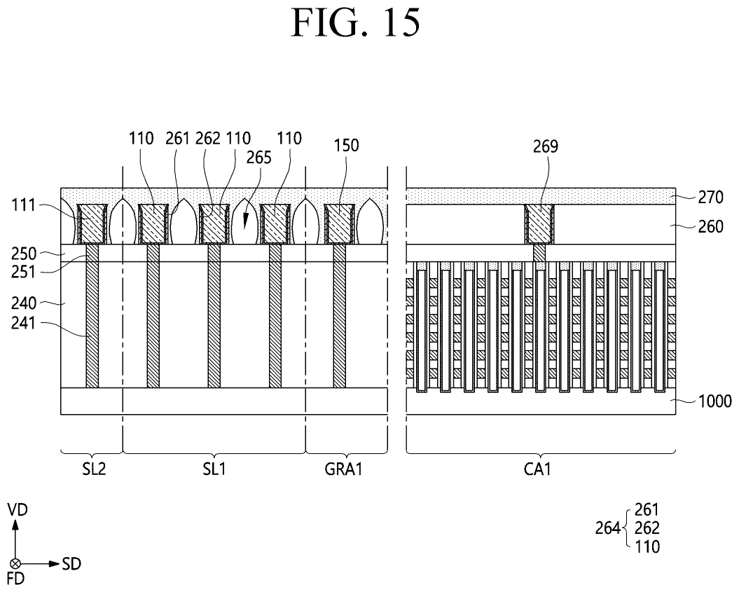

Referring to FIG. 15, a first insulating layer 270 may be formed on the second insulating layer 260 and the first wiring 269 in the first chip region CA1. In the first guard ring region GRA1 and the first scribe lane region SL1, a first insulating layer 270 may be formed over the second upper insulating layer 250, the guard ring wiring 150, and the plurality of dummy wirings 110. The process of forming the first insulating layer 270 may include depositing an insulating material and performing a planarization process on the insulating material. The planarization process may include chemical mechanical polishing (CMP). An upper surface of the first insulating layer 270 may form a flat planar surface.

The insulating material of the first insulating layer 270 may include an insulating material having an overhang property. As the insulating material of the first insulating layer 270 is deposited over the upper and side surfaces of the plurality of dummy wirings 110, an overhanging structure may be formed between adjacent dummy wirings 110. For example, the width of the insulating material deposited on the upper surface of the wiring structure 264 may be greater than that of the insulating material deposited on the side surfaces the wiring structure 264. As a result, the insulating material deposited on the top surface of one of the adjacent wiring structures 264 may be in contact with the insulating material deposited on the top surface of another adjacent wiring structure 264. In contrast, the insulating material deposited on the side surface of one of the adjacent wiring structures 264 may be spaced apart from the insulating material deposited on the side surface of the other adjacent wiring structure 264. Accordingly, the air gap 265 may be formed between the adjacent wiring structures 264.

Likewise, the insulating material of the first insulating layer 270 may form an overhanging structure between a dummy wiring adjacent to the first chip region CA1 among the plurality of dummy wirings 110 and the guard ring wiring 150. As a result, the air gap 265 may be formed between the guard ring wiring 150 and the dummy wiring adjacent to the first chip region CA1 among the plurality of dummy wirings 110.

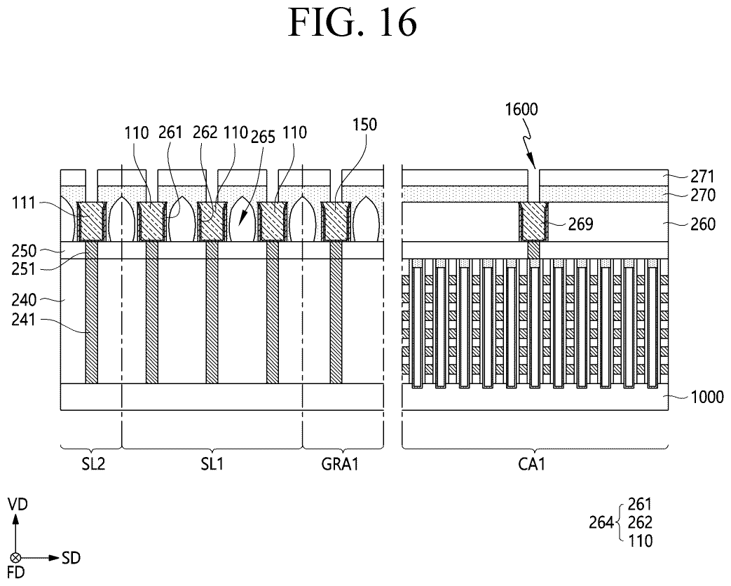

Referring to FIG. 16, a first upper insulating layer 271 may be formed on the first insulating layer 270. A plurality of second trenches 1600 may be formed in the first insulating layer 270 and the first upper insulating layer 271. The process of forming the second trenches 1600 may include a photolithography or etching process. Through this process, the upper surfaces of the first wiring 269, the dummy wirings 110, and the guard ring wiring 150 may be exposed.

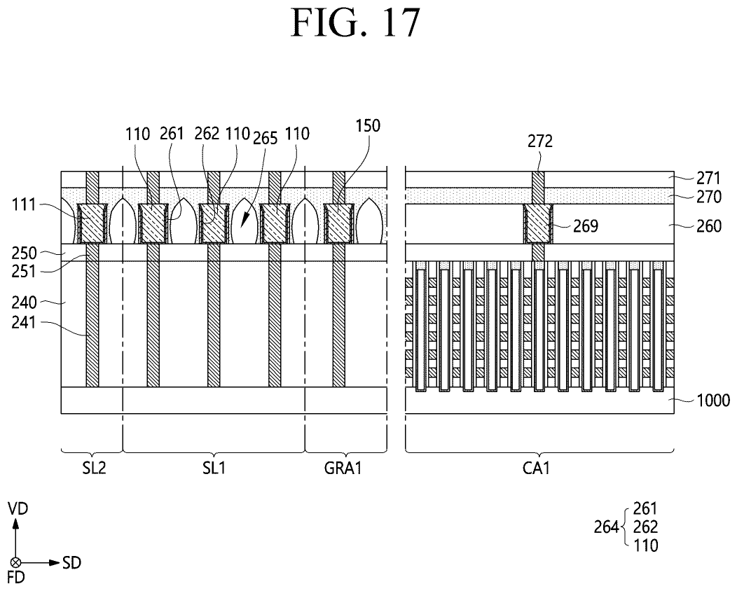

Referring to FIG. 17, second bonding contacts 272 in contact with the plurality of dummy wirings may be formed in the first insulating layer 270 and the first upper insulating layer 271. The process of forming the second bonding contacts 272 may include depositing a conductive material and planarizing the conductive material. The planarization process may include grinding or chemical mechanical polishing (CMP). An upper surface of the second bonding contact 272 may be substantially coplanar with the upper surface of the first insulating layer 270. The conductive material may include metal, metal oxide, metal nitride, metal silicide, polysilicon, conductive carbon, or a combination thereof.

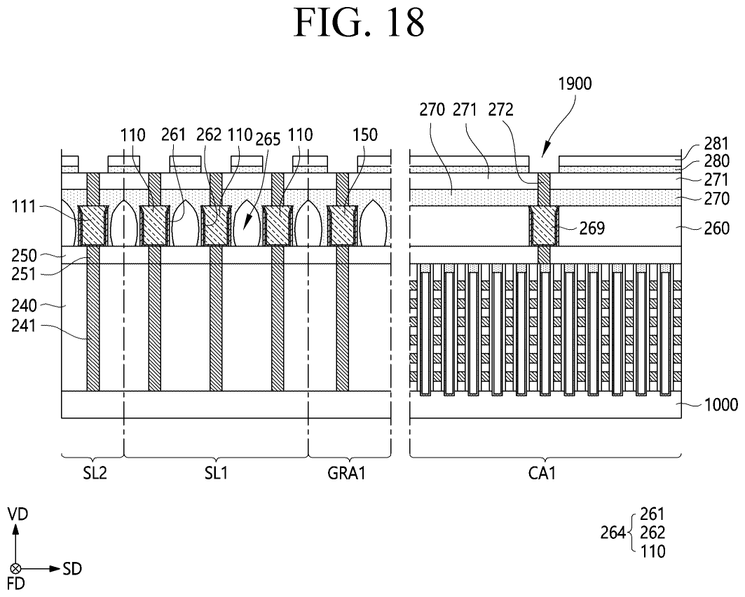

Referring to FIG. 18, a third bonding insulating layer 280 may be formed on the first upper insulating layer 271 and the second bonding contact 272. A second bonding insulating layer 281 may be formed on the third bonding insulating layer 280. A plurality of third trenches 1900 may be formed over the second bonding contact 272 within the second bonding insulating layer 281 and the third bonding insulating layer 280. As a result of forming the third trenches 1900, the upper surface of the second bonding contact 272 may be exposed. The process of forming the third trenches 1900 may include a photolithography or etching process.

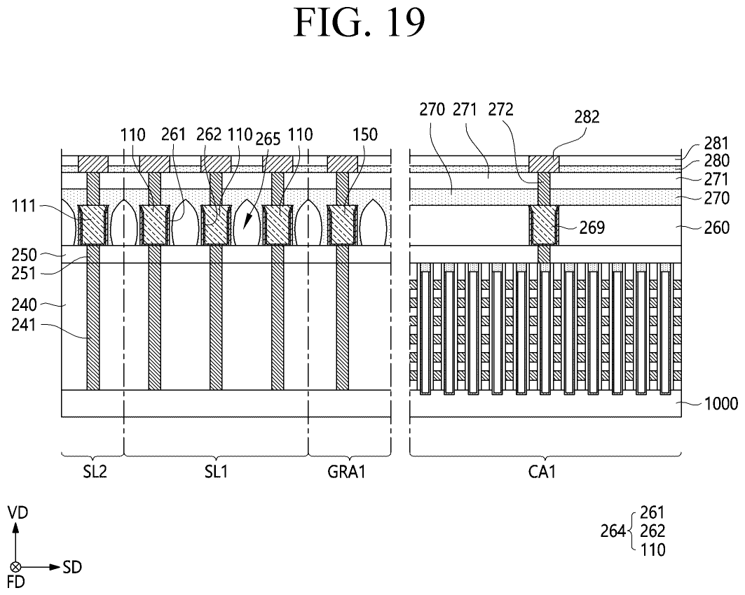

Referring to FIG. 19, a second bonding pad 282 may be formed on the second bonding contact 272. The second bonding pad 282 may be formed to fill the space of the third trenches 1900 within the second bonding insulating layer 281 and the third bonding insulating layer 280. The process of forming the second bonding pad 282 may include depositing a conductive material and performing a planarization process on the conductive material. The planarization process may include grinding or chemical mechanical polishing (CMP). An upper surface of the second bonding pad 282 may be substantially coplanar with the upper surface of the second bonding insulating layer 281. The conductive material may include metal, metal oxide, metal nitride, metal silicide, polysilicon, conductive carbon, or a combination thereof.

Referring back to FIG. 2, the first semiconductor structure S1 is prepared. The second bonding pad 282 and the second bonding insulating layer 281 of the second semiconductor structure S2 may be bonded to the first bonding pad 222 and the first bonding insulating layer 225 of the first semiconductor structure S1. After bonding the second semiconductor structure S2 to the first semiconductor structure S1, the first substrate 1000 may be removed. The process of removing the first substrate 1000 may include an etching process, grinding process, or chemical mechanical polishing (CMP). After removing the first substrate 1000, a source plate 238 may be formed over the channel structure 233 and the interlayer insulating layer 232 in the first chip region CA1. A fourth upper insulating layer 290 may be formed over the source plate 238, the third upper insulating layer 240, and the second upper contact 241. The process of forming the fourth upper insulating layer 290 may include depositing an insulating material and performing a planarization process on the insulating material. The planarization process may include grinding or CMP. A third upper contact 292 may be formed to penetrate the fourth upper insulating layer 290. A fifth upper insulating layer 291 and an upper wiring 293 may be formed over the third upper contact 292 and the fourth upper insulating layer 290. The process of forming the third upper contact 292 and the upper wiring 293 may include a damascene process.

According to embodiments of the present disclosure, damage to the chip region CA or the guard ring region GRA during die separation can be minimized. Specifically, the air gap 265, which is disposed in an overlap region located between the plurality of dummy wirings 110 in the scribe lane region SL, may guide a straight-cut separation within the scribe lane region SL during chip separation, without encroaching on the chip region CA or the guard ring region GRA. Accordingly, embodiments of the present disclosure improve wafer chip quality and increase process yield.

Although various embodiments of the disclosed technology have been described with particular specifics and varying details for illustrative purposes, those skilled in the art will appreciate that various modifications, additions, and substitutions may be made based on what is disclosed or illustrated in the present disclosure without departing from the spirit and scope of the invention as defined in the following claims.

What is claimed is:

1. A semiconductor device comprising:
a substrate including a chip region and a scribe lane region disposed around the chip region;
a bonding pad disposed on the substrate;
a plurality of dummy wirings connected to the bonding pad, arranged in a first direction within the scribe lane region, and including a first dummy wiring and a second dummy wiring disposed adjacent to each other in a second direction intersecting the first direction; and
a first insulating layer disposed on side surfaces and bottom surfaces of the plurality of dummy wirings, including a first overlap region located between the first dummy wiring and the second dummy wiring in the second direction, wherein a first air gap is disposed in the first overlap region.

2. The semiconductor device of claim 1,
wherein a width of the first overlap region in the first direction is less than a width of the first dummy wiring in the first direction.

3. The semiconductor device of claim 1,
wherein a width of the first overlap region in the first direction is equal to a width of the first dummy wiring in the first direction.

4. The semiconductor device of claim 1,
wherein the plurality of dummy wirings further include a third dummy wiring and a fourth dummy wiring spaced apart from the first dummy wiring and the second dummy wiring, respectively, in the first direction,
wherein the first insulating layer further includes a second overlap region entirely located between the third dummy wiring and the fourth dummy wiring in the second direction,
wherein a second air gap is disposed in the second overlap region, and
wherein the first overlap region and the second overlap region are spaced apart from each other in the first direction.

5. The semiconductor device of claim 1,
wherein the plurality of dummy wirings further include a third dummy wiring spaced apart from the second dummy wiring, respectively, in the first direction,
wherein the first insulating layer further includes a second overlap region entirely located between the second dummy wiring and the third dummy wiring in the second direction,
wherein a second air gap is disposed in the second overlap region, and
wherein the first overlap region and the second overlap region are spaced apart from each other in the first direction.

6. The semiconductor device of claim 1,
wherein the plurality of dummy wirings further includes a third dummy wiring adjacent to the second dummy wiring in the second direction and disposed farther from the chip region than the second dummy wiring in the second direction,
wherein the first insulating layer further includes a second overlap region entirely located between the second dummy wiring and the third dummy wiring in the second direction,
wherein a second air gap is disposed in the second overlap region, and
wherein opposing ends of the first overlap region in the first direction are spaced apart from corresponding opposing ends of the second overlap region in the first direction.

7. The semiconductor device of claim 1,
wherein the scribe lane region includes an inner region adjacent to the chip region and an outer region spaced apart from the chip region in the second direction, and
wherein the plurality of dummy wirings are disposed in the inner region.

8. The semiconductor device of claim 7,
wherein the plurality of dummy wirings are disposed in the inner region and the outer region, and
wherein the first insulating layer located on an outer side surface of a dummy wiring, among the plurality of dummy wirings, that is farthest from the chip region is recessed toward the chip region.

9. The semiconductor device of claim 1,
wherein the substrate further includes a guard ring region between the chip region and the scribe lane region,
wherein a guard ring is disposed in the guard ring region,
wherein the first insulating layer further includes a third overlap region entirely located between the guard ring and a dummy wiring among the plurality of dummy wirings closest to the chip region, in the second direction, and
wherein a third air gap is disposed in the third overlap region.

10. The semiconductor device of claim 9,
wherein the chip region includes a first wiring,
wherein the first insulating layer is located between the first wiring and the guard ring in the second direction, and
wherein the second air gap is located between the first wiring and the guard ring, within the first insulating layer.

11. A semiconductor device comprising:
a first semiconductor structure and a second semiconductor structure each including a chip region and a scribe lane region surrounding the chip region,
wherein the first semiconductor structure includes a peripheral circuit and a peripheral bonding pad connected to the peripheral circuit, and
wherein the second semiconductor structure comprises:
a cell bonding pad bonded to the peripheral bonding pad;
a plurality of dummy wirings disposed in the scribe lane region and connected to the cell bonding pad; and
a first insulating layer covering side surfaces and bottom surfaces of the plurality of dummy wirings, wherein a first air gap is disposed between the plurality of dummy wirings.

12. The semiconductor device of claim 11,
wherein the first semiconductor structure and the second semiconductor structure each further include a guard ring region between the chip region and the scribe lane region,
wherein a guard ring is disposed in the guard ring region of the second semiconductor structure, and
wherein a second air gap is disposed between the guard ring and a dummy wiring that is closest to the guard ring, among the plurality of dummy wirings.

13. The semiconductor device of claim 12,
wherein the second semiconductor structure further includes a first wiring disposed in the chip region, and
wherein the second air gap is disposed between the first wiring and the guard ring.

14. The semiconductor device of claim 11,
wherein the first air gap is disposed on a side surface of a dummy wiring, among the plurality of dummy wirings, that is farthest from the chip region.

15. The semiconductor device of claim 11,
wherein the scribe lane region includes an inner region adjacent to the chip region and an outer region spaced apart from the chip region in a second direction, and
wherein the plurality of dummy wirings are disposed in the inner region.

16. The semiconductor device of claim 11,
wherein the plurality of dummy wirings includes a first dummy wiring and a second dummy wiring adjacent to each other in a second direction, and
wherein an upper surface of the first insulating layer on a side surface of the first dummy wiring is separated from an upper surface of the first insulating layer disposed on a side surface of the second dummy wiring.

17. The semiconductor device of claim 11,
wherein each of the plurality of dummy wirings includes a first wiring portion and a second wiring portion continuous with the first wiring portion, the second wiring portion having a maximum width in the second direction greater than a width of the first wiring portion in the second direction.

18. The semiconductor device of claim 17,
further comprising a barrier layer disposed on side surfaces of the plurality of dummy wirings,
wherein the barrier layer comprises:
a first barrier portion disposed on a side surface of the first wiring portion; and
a second barrier portion disposed on a side surface of the second wiring portion, and
wherein the second barrier portion protrudes further in the second direction than the first barrier portion.

19. The semiconductor device of claim 11,
further comprising a plurality of spacers disposed on side surfaces of the plurality of dummy wirings,
wherein the plurality of spacers includes a first spacer portion and a second spacer portion continuous with the first spacer portion, and
wherein a maximum width of the second spacer portion is less than a width of the first spacer portion.

20. A semiconductor device comprising:
a substrate including a chip region and a scribe lane region disposed around the chip region;
a plurality of dummy wirings disposed in the scribe lane region on the substrate, arranged in a first direction, and including a first dummy wiring and a second dummy wiring adjacent to each other in a second direction intersecting the first direction; and
a first insulating layer disposed on side surfaces and bottom surfaces of the plurality of dummy wirings, including a first overlap region located between the first dummy wiring and the second dummy wiring in the second direction,
wherein a width of the first overlap region in the first direction is less than a width of the first dummy wiring in the first direction, and
wherein an air gap is disposed in the first overlap region.
